(19) United States
(12) Patent Application Publication
(10) Pub. No.: US 2006/0182538 A1
(43) Pub. Date: Aug. 17, 2006

(54) Wafer transfer apparatus having two independently movable transfer modules

(75) Inventors: Jae Suk Lee, Icheon-si (KR); June Woo Lee, Osan-si (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Gangnam-Gu (KR)

(21) Appl. No.: 11/320,466

(22) Filed: Dec. 29, 2005

(30) Foreign Application Priority Data
Dec. 29, 2004 (KR) 10-2004-0115753

(51) Int. Cl. H01L 21/677

(52) U.S. Cl. 414/217

(57) ABSTRACT

A wafer transfer apparatus having two independently movable transfer modules. The apparatus that transfers the wafers from one chamber to another includes a first transfer module and a second transfer module. Each module has a robot arm and at least one blade. Each robot arm freely rotates along the chambers, and each blade is rotatably connected to the robot arm. The first and second transfer modules move independently in same or different directions. Each transfer module may have two blades, which are joined respectively to upper and lower parts of the robot arm. Furthermore, the first and second transfer modules can maintain an angle of at least one hundred twenty degrees, whereby preventing the wafers from being overlapped in transit.

### CROSS REFERENCE TO RELATED APPLICATIONS

This U.S. non-provisional application claims priority under 35 U.S.C. §119 from Korean Patent Application No. 2004-115753, which was filed in the Korean Intellectual Property Office on Dec. 29, 2004, the contents of which are incorporated by reference herein in its entirety.

### BACKGROUND OF THE INVENTION

1. Field of the Invention

The present invention relates generally to a wafer transferring technique in semiconductor fabrication and, more particularly, to a wafer transfer apparatus that has two independently movable transfer modules.

2. Description of the Related Art

In general, semiconductor devices are fabricated in and on a wafer through a great variety of processes such as diffusion, deposition, ion implantation, photo etching, etc. The processes for fabricating the wafer are very susceptible to particles, so such processes should be performed in a vacuum chamber restricted within few particles.

The wafer may be polluted with particles while the wafer moves between different chambers. Not only to prevent such potential problems, but also to shorten the entire process time, advanced processes for wafer fabrication are often performed in a multi-chamber that allows in-situ processes.

FIG. 1 schematically shows, in a plan view, a conventional wafer transfer apparatus in a multi-chamber of a cluster type.

Referring to FIG. 1, the multi-chamber is composed of, for example, two loadlock chambers 1 and four process chambers 3, which are disposed in a circle. A single wafer transfer module 8 is provided in the multi-chamber so as to transfer the wafer to and from each chamber 1 and 3. The transfer module 8 has one robot arm 5 and one blade 7. The robot arm 5 can freely rotate along all the chambers 1 and 3, and further, the blade 7 is rotatably connected to the robot arm 5. The blade 7 fixedly supports the wafer by means of vacuum force, for example.

Typically, the transfer module 8 takes charge of all movements of the wafers between the chambers in the multi-chamber, that is, all wafer-transferring actions between the loadlock chamber 1 and the process chamber 3, and between different process chambers 3. Therefore, while the transfer module 8 is transferring a certain wafer, remaining wafers should wait their turns even though their processes are completed in the process chamber 3. Unfortunately, this may cause a great loss in throughput, which becomes more serious in case of shorter process time, more chambers, and a slower robot arm.

### SUMMARY OF THE INVENTION

Exemplary, non-limiting embodiments of the present invention provide a wafer transfer apparatus that can allow efficient transferring actions of the wafers in semiconductor fabrication equipment.

According to one exemplary embodiment of the present invention, the apparatus, which transfers wafers from one chamber to another in a wafer fabrication equipment having a plurality of chambers, comprises a first transfer module and a second transfer module, each of which has a robot arm and at least one blade. Each robot arm freely rotates along the chambers, and each blade is rotatably connected to the robot arm. The first and second transfer modules move independently in same or different directions.

In the apparatus, each transfer module can have two blades, which are joined respectively to upper and lower parts of the robot arm.

Furthermore, the first and second transfer modules can maintain an angle of at least one hundred twenty degrees, whereby preventing the wafers from being overlapped in transit.

### BRIEF DESCRIPTION OF THE DRAWINGS

FIG. 1 is a plan view schematically showing a conventional wafer transfer apparatus in the multi-chamber of cluster type.

FIG. 2 is a plan view schematically showing a wafer transfer apparatus in accordance with an exemplary embodiment of the present invention.

FIG. 3 is a cross-sectional view showing actions of the wafer transfer apparatus in the loadlock chamber.

FIG. 4 is a cross-sectional view showing actions of the wafer transfer apparatus in the process chamber.

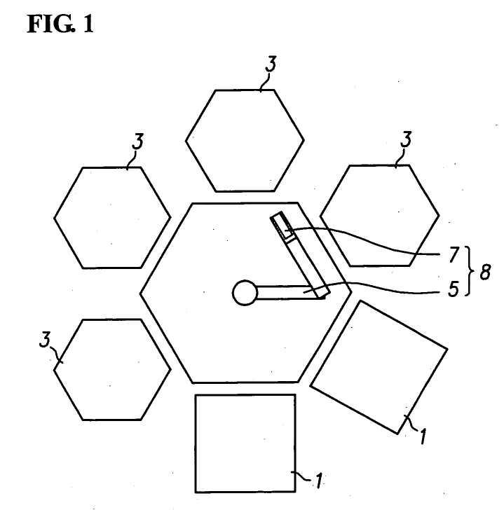

### DETAILED DESCRIPTION OF EXEMPLARY EMBODIMENTS OF THE INVENTION

An exemplary, non-limiting embodiment of the present invention will now be described more fully hereinafter with reference to the accompanying drawings. This invention may, however, be embodied in many different forms and should not be construed as limited to the exemplary embodiment set forth herein. Rather, the disclosed embodiment is provided so that this disclosure will be thorough and complete, and will fully convey the scope of the invention to those skilled in the art. The principles and features of this invention may be employed in varied and numerous embodiments without departing from the scope of the invention.

In is noted that well-known structures and processes are not described or illustrated in detail to avoid obscuring the essence of the present invention. It is also noted that the figures are not drawn to scale. Rather, for simplicity and clarity of illustration, the dimensions of some of the elements are exaggerated relative to other elements.

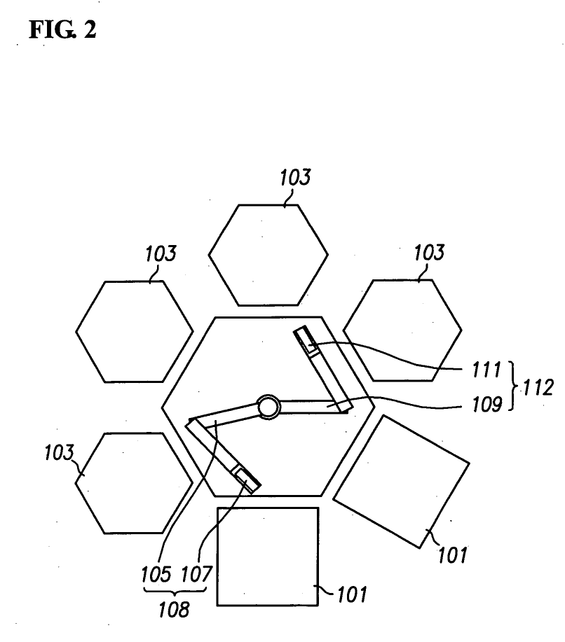

FIG. 2 schematically shows, in a plan view, a wafer transfer apparatus in accordance with an exemplary embodiment of the present invention.

Referring to FIG. 2, two loadlock chambers 101 and four process chambers 103 constitute a multi-chamber for wafer fabrication. The number of chambers 101 and 103 is not restricted to the current embodiment. As is well known in the art, the loadlock chamber 101 temporarily receives the wafers to be loaded into or to have been unloaded from the process chambers. The process chamber 103 is a vacuum chamber in which a specific process is performed for the wafer. The loadlock chambers 101 and the process chambers 103 are typically disposed in a circle.

The wafer transfer apparatus includes two wafer transfer modules, i.e., a first transfer module 108 and a second transfer module 112, each of which transfers the wafer to and from the chambers 101 and 103. Both the transfer modules 108 and 112 always maintain an angle of at least one hundred twenty degrees so as to prevent the wafers from being overlapped in transit. Each transfer module 108, 112 has a robot arm 105, 109, respectively, and a blade 107, 111, respectively. In an alternative embodiment, each transfer module 108, 112 can have two blades.

The transfer modules 108 and 112 can move independently in same or different directions. Each robot arm 105, 109 can freely rotate along all the chambers 101 and 103, and further, each blade 107, 111 is rotatably connected to the robot arm 105, 109. The blade 107, 111 fixedly supports the wafer by means of vacuum force, for example. If two blades are provided for each robot arm, such blades are joined respectively to the upper and lower parts of the robot arm. In addition, such blades can move separately and rotate in different directions.

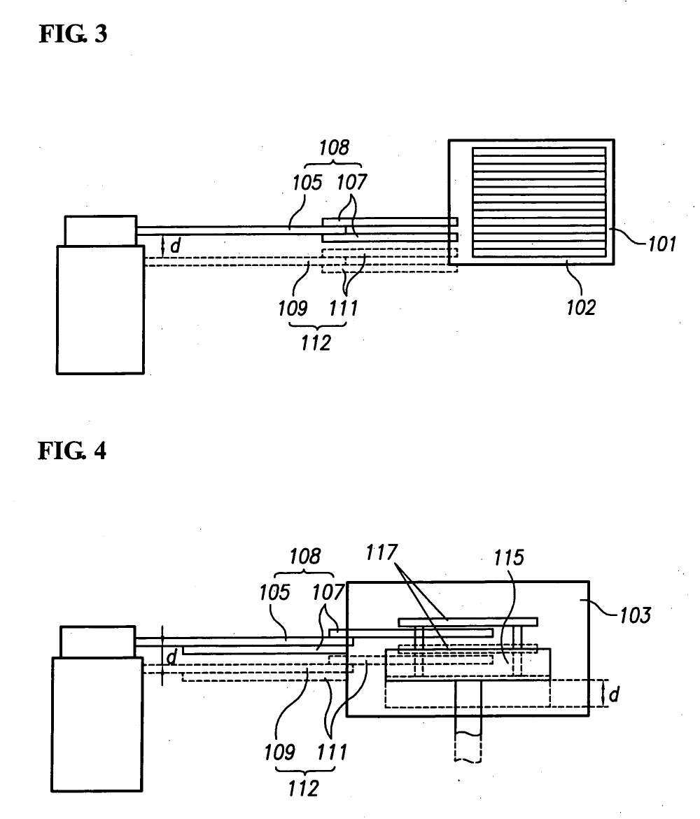

As discussed above, each transfer module 108, 112 transfers the wafers from one chamber to another. FIG. 3 shows, in a cross-sectional view, actions of the wafer transfer apparatus in the loadlock chamber.

Referring to FIG. 3, the robot arm 105 of the first transfer module 108 moves in front of one of the loadlock chambers 101, and the blade 107 enters a wafer cassette 102 provided in the loadlock chamber 101. Then the blade 107 holds up a wafer from the wafer cassette 102 or puts down the wafer into the wafer cassette 102.

Subsequently, the robot arm 109 of the second transfer module 112 moves in front of the loadlock chamber 101, and the blade 111 enters the wafer cassette 102 in the loadlock chamber 101. Then the blade 111 holds up another wafer from the wafer cassette 102 or puts down the wafer into the wafer cassette 102. The second transfer module 112 is located at a distance (d) from the first transfer module 108. Hence, the second transfer module 112 can take out or put in the wafer from or to a different position of the wafer cassette 102. Furthermore, the wafer cassette 102 can move vertically by means of a well-known elevating system. At this time, the first transfer module 108 can perform another transferring actions in another chamber.

FIG. 4 shows, in a cross-sectional view, actions of the wafer transfer apparatus in the process chamber.

Referring to FIG. 4, the robot arm 105 of the first transfer module 108 moves in front of one of the process chambers 103, and the blade 107 enters the process chamber 103 having a chuck 115 provided therein. Then the blade 107 holds up a wafer 117 from the chuck 115 or puts down the wafer 117 onto the chuck 115.

Subsequently, the robot arm 109 of the second transfer module 112 moves in front of the process chamber 103, and the blade 111 enters the process chamber 103. Then the blade 111 holds up another wafer from the chuck 115 or puts down the wafer onto the chuck 115. The chuck 115 can move vertically to a distance (d) between the first and second transfer modules 108 and 112. At this time, the first transfer module 108 can perform another transferring actions in another chamber.

As discussed hereinbefore, the wafer transfer apparatus according to the present invention has two independently movable transfer modules that perform separate transferring actions for the wafers. Accordingly, the wafer transfer apparatus of the invention allows efficient actions of transferring the wafers in semiconductor fabrication equipment, thereby enhancing throughput of a multi-chamber in wafer fabrication. Additionally, since the wafer transfer apparatus does not overlap the wafers in transit, there never occurs any pollution of the wafer due to mechanically induced particles.

While this invention has been particularly shown and described with reference to an exemplary embodiment thereof, it will be understood by those skilled in the art that various changes in form and details may be made therein without departing from the spirit and scope of the invention as defined by the appended claims.

What is claimed is:

1. A wafer transfer apparatus that transfers wafers from one chamber to another in a wafer fabrication equipment having a plurality of chambers, the apparatus comprising:
a first transfer module having a first robot arm and at least one first blade, the first robot arm freely rotating along the chambers, and the first blade being rotatably connected to the first robot arm; and
a second transfer module having a second robot arm and at least one second blade, the second robot arm freely rotating along the chambers, and the second blade being rotatably connected to the second robot arm,
wherein the first and second transfer modules move independently in same or different directions.

2. The apparatus of claim 1, wherein each transfer module has two blades, which are joined respectively to upper and lower parts of the robot arm.

3. The apparatus of claim 1, wherein the first and second transfer modules maintain an angle of at least one hundred twenty degrees, whereby preventing the wafers from being overlapped in transit.
